(19) United States
(12) Patent Application Publication
(10) Pub. No.: US 2013/0193955 A1
(43) Pub. Date: Aug. 1, 2013

(54) Locator

(71) Applicants: Reiner Krapf, Filderstadt (DE); Tobias Zibold, Stuttgart (DE); Andrej Albrecht, Stuttgart (DE)

(72) Inventors: Reiner Krapf, Filderstadt (DE); Tobias Zibold, Stuttgart (DE); Andrej Albrecht, Stuttgart (DE)

(73) Assignee: ROBERT BOSCH GmbH, Stuttgart (DE)

(21) Appl. No.: 13/696,055

(22) PCT Filed: Mar. 17, 2011
(86) PCT No.: PCT/EP2011/054016

§ 371 Date: Feb. 21, 2013

(30) Foreign Application Priority Data
May 7, 2010 (DE) 10 2010 028 719.9

(51) Int. Cl. G01R 33/00

(52) U.S. Cl. CPC G01R 33/0011
USPC 324/207.12

(57) ABSTRACT

A locator for detecting an article includes a push-pull measurement bridge configured to actuate a first and a second electromagnetic device in a variable ratio. Depending on the actuation the first electromagnetic device generates an alternating electromagnetic field in the region of the article. The locator further includes a comparator for detecting the article, should the variable ratio differ by more than a predetermined amount from a predetermined ratio.

The invention relates to a locator. In particular, the invention relates to a locator having the features of claim 1 for sensing an article.

### PRIOR ART

Various locators are known for sensing an article concealed in a wall. The article concealed in the wall may be a water, power or gas line, for example, which must not be damaged when working on the wall. On the other hand, the article may also be a wooden beam or another supporting structure, and the work needs to be carried out in the region of the supporting structure.

In order to trace a metallic article, such as a steel water pipe, within the wall, a magnetic field is usually produced and a check is performed to determine whether the article influences the magnetic field. If the influence exceeds a predetermined amount, the article is sensed. A nonmetallic article, such as a wooden beam, can be detected by using its dielectric properties. To this end, an electrical field is produced and a check is performed to determine the extent to which the article influences the electrical field. The article is sensed if the influence exceeds a predetermined amount. If the article is a conductor carrying current or voltage, it is also possible to detect an electromagnetic field surrounding the conductor. Articles which are neither metallic nor have easily detectable dielectric properties, such as a copper power line encased in plastic, can be sensed in this way.

A fundamental problem for locators is that they tend to produce false measurements when a sensing sensitivity is increased. The locators therefore need to be calibrated by a user in the region of the measurement location. The calibration can render the measurement process complex and ambiguous.

The invention is based on the object of providing a sensitive locator which is easy to use.

### DISCLOSURE OF THE INVENTION

The invention solves the problem by means of a locator having the features of claim 1. Subclaims render preferred embodiments.

A locator according to the invention for sensing an article comprises a push-pull measurement bridge for actuating a first and a second electromagnetic device in a variable ratio. The first electromagnetic device takes the actuation as a basis for producing an electromagnetic alternating field in the region of the article. A comparator in the locator senses the article if the variable ratio differs from a predetermined ratio by more than a predetermined amount.

The push-pull measurement bridge is known in principle from other applications in the prior art, for example from DE 10 2008 005 783 A1. The push-pull measurement bridge can be used for field-compensated measurement, as a result of which it is possible to combine a large measurement region with a high level of sensitivity for the locator. In addition, the push-pull measurement bridge can be used for differential measurement, which means that it is possible to dispense with calibration by a user of the locator. The push-pull measurement bridge can be used for measurement alternatively by means of a magnetic or electrical field. The respective other component of the electromagnetic field is virtually zero in this case.

In one embodiment, the first electromagnetic device can successively produce a magnetic field and an electrical field in the region of the article. To this end, the electromagnetic device may comprise a coil and an electrode which are successively connected to the push-pull measurement bridge.

In one embodiment, electromagnetic devices that correspond to one another are used. In this case, the push-pull measurement bridge may be of a design such that a third electromagnetic device takes on a field which has the variable ratio in respect of the other two electromagnetic devices. Alternatively, electrical parameters from the first and second electromagnetic devices can be compared with one another in order to determine the variable ratio. In a further embodiment, the second electromagnetic device does not produce a field, but rather forms an electrical load for the push-pull measurement bridge, which forms the variable ratio with the electrical load from the first electromagnetic device.

In addition, the locator may comprise an apparatus for determining an electrical field from the article, with the article being sensed successively on the basis of the push-pull measurement bridge and the apparatus. Preferably, the article is sensed when it is sensed by means of at least one of the three approaches described. In this case, an output device in the locator can, upon sensing the article, output a signal which indicates on the basis of what type of field the article has been sensed. A first signal can then be a measurement which has been performed by means of the push-pull measurement bridge and a magnetic field, a second signal can indicate a measurement which has been performed by means of the push-pull measurement bridge and an electrical field, and a third signal can then be a measurement which has been performed by means of the apparatus for determining the electrical field from the article. The signal may be at least one from a choice of visual and audible.

The locator may have a multiplicity of first electromagnetic devices which are arranged next to one another and which are successively operated on the push-pull measurement bridge. This allows the article to be sensed in one or two dimensions, which means that the article can be localized more precisely or a boundary of the article, for example an edge, can be found more easily.

In one preferred embodiment, the measurement results attained using the various first electromagnetic devices are visually displayed by defining display regions on a visual output device which are each associated with one of the first electromagnetic devices. In this case, the arrangement of the display regions preferably corresponds to the arrangement of the first electromagnetic devices. A user can thus be presented with a visual representation of the measurement result which can be grasped intuitively and has a high level of detail.

A distance of the article from the locator can correspond to a change of color in the visual output device. If the visual output device is kept simple, and hence inexpensive, for example in the form of a few light-emitting diodes, then a change of color allows the measurement result to be presented more precisely with little complexity, it being possible to use multicolored LEDs. If the visual output device is more complex, for example in the form of a graphical panel output with color capability, such as a liquid-crystal display with graphics capability, then the distance of the article can be presented graphically by a false color presentation. In this case too, the color presentation of the measurement results can lead to improved ease of use for a user.

The locator may comprise a device for a user to alter the predetermined amount. This allows the user to set the sensitivity of the locator. The predetermined amount can be set in line with a gain for control signals which are supplied to the first and second electromagnetic devices, so that the electromagnetic fields produced are amplified accordingly. In one embodiment, the predetermined amount can be changed over between a plurality of predetermined values, for example two or three values, so that the locator has various sensitivities which can simply be selected by the user.

A distance sensor may be provided in order to ensure that the locator is lying flat on a measurement area. The measurement area is usually an essentially planar area in a region of the locator, for example a wall, particularly a lightweight wall, a ceiling or a floor. A side of the locator that faces the measurement area is usually also planar, and the distance sensor monitors an at least approximate degree of parallelism between the measurement area and the locator. If the locator is not lying on the measurement area in sufficiently planar fashion, the predetermined ratio can be adapted in line with the deviation from the degree of parallelism, in order to keep the measurement result constant. In addition or alternatively, a warning can be output to the user of the locator.

The locator may also comprise a displacement sensor for sensing a displacement of the locator relative to the article, wherein the locator is designed to associate a measurement result from the push-pull measurement bridge with a displacement position. This means that a user can be provided with the capability of sweeping over a measurement region with the locator and thereby recording a large number of measurement results which can then be presented graphically, for example. In one embodiment, an image detail and/or a magnification level from/for the graphical presentation can be selected and presented on the visual display device of the locator.

The locator may comprise a further push-pull measurement bridge having a further first and a further second electromagnetic device, wherein the first electromagnetic device of the push-pull measurement bridge produces an electromagnetic field with a negligibly small magnetic component, while the first electromagnetic device of the further push-pull measurement bridge produces an electromagnetic field with a negligibly small electrical component, in order to sense the article on the basis of an electrical field and a magnetic field simultaneously.

### BRIEF DESCRIPTION OF THE FIGS.

The text below describes the invention in more detail with reference to the appended figures, in which:

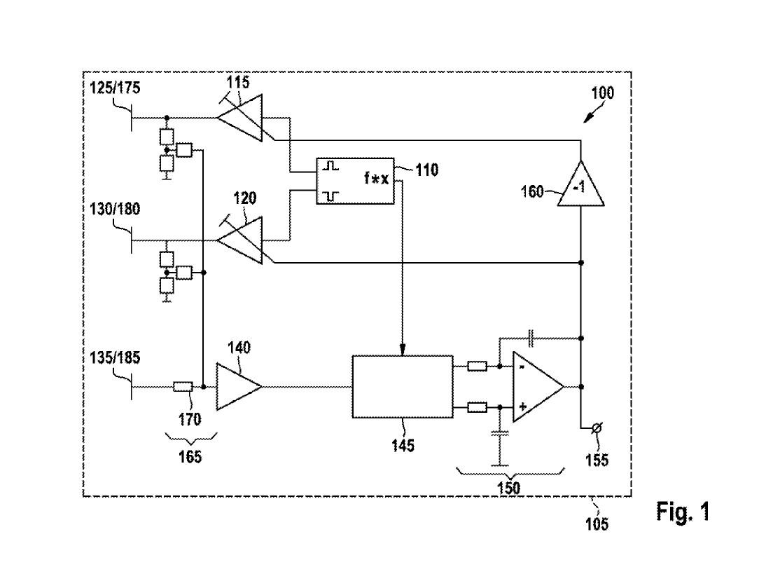

FIG. 1 shows a block diagram of a push-pull measurement bridge;

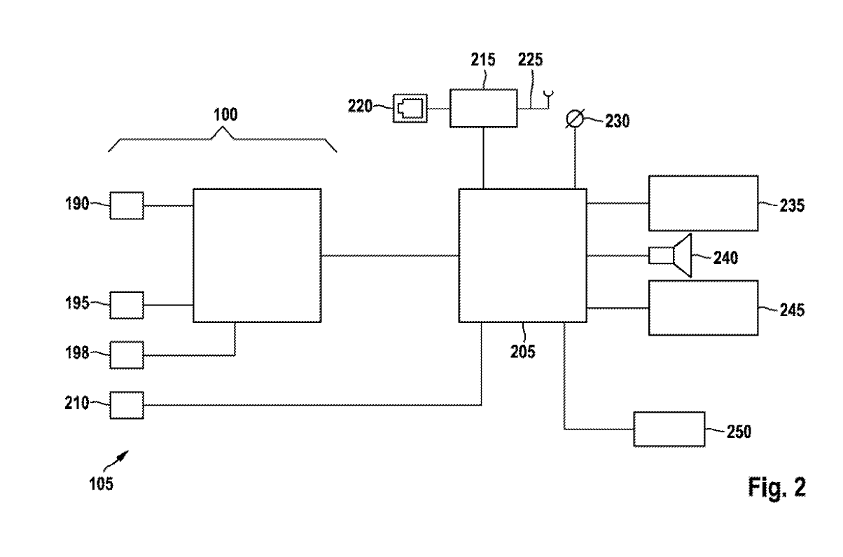

FIG. 2 shows a locator with the push-pull measurement bridge from FIG. 1;

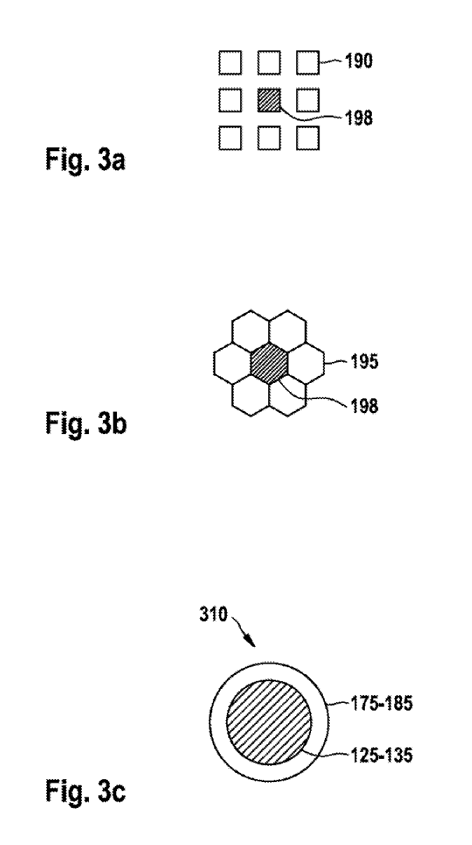

FIG. 3 shows various electromagnetic devices in the push-pull measurement bridge from FIG. 1;

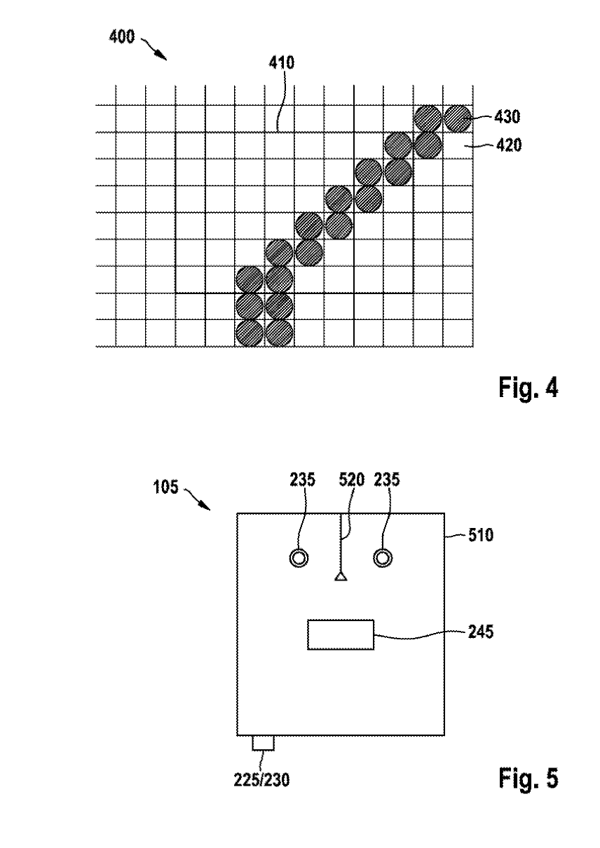

FIG. 4 shows a visual display of a graphical display on the locator from FIG. 2; and

FIG. 5 shows a view of an exemplary locator as shown in FIG. 3.

### PRECISE DESCRIPTION OF EXEMPLARY EMBODIMENTS

FIG. 1 shows a block diagram of a push-pull measurement bridge 100. The push-pull measurement bridge 100 is part of a locator 105 for sensing articles. Depending on the embodiment, the push-pull measurement bridge 100 can be used for sensing a dielectric article, for example made of wood, or for sensing a metallic article, for example made of steel. The text below first of all describes the embodiment which can be used to sense a dielectric article.

A clock generator 110 has two outputs at which it provides periodic alternating signals having a phase shift, preferably a 180° phase shift. The alternating signals may comprise square-wave, triangular-waveform or sinusoidal signals, in particular. The outputs of the clock generator are connected to a first controllable amplifier 115 and a second controllable amplifier 120, respectively. Each of the controllable amplifiers 115, 120 has a control input which it uses to receive a signal which controls a gain factor of the controllable amplifier 115, 120. An output of the first controllable amplifier 115 is connected to a first transmission electrode 125 and an output of the second controllable amplifier 120 is connected to a second transmission electrode 130.

A reception electrode 135 is used as a potential probe and is connected to an input amplifier 140; a compensating network 165 that is shown in the region of the electrodes 125-135 is not considered at first and an impedance 170 is dispensed with. The input amplifier 140 is shown with a constant gain factor; in other embodiments, however, a gain factor of the input amplifier 140 may also be controllable. By way of example, this allows a spatial resolution and/or sensitivity of the push-pull measurement bridge 100 to be influenceable and, by way of example, to be controllable on the basis of a measurement signal on the input amplifier 140.

The output of the input amplifier 140 is connected to a synchronous demodulator 145. The synchronous demodulator 145 is also connected to the clock generator 110 and receives from the latter a clock signal which indicates the phase of the signals provided at the outputs of the clock generator 110. In a simple embodiment, in which the signals provided by the clock generator 110 are symmetrical square-wave signals, one of the output signals routed to the controllable amplifiers 115, 120 can be used as a clock signal. The synchronous demodulator 145 essentially takes the clock signal provided by the clock generator 110 as a basis for connecting the measurement signal received from the input amplifier 140 alternately to its upper or lower output.

The two outputs of the synchronous demodulator 145 are connected to an integrator (integrating comparator) 150, which in this case is shown as an operational amplifier connected up to two resistors and two capacitors. Other embodiments are likewise possible, for example as an active low-pass filter. A digital implementation in the connection to the synchronous demodulator 145 is also conceivable, in the case of which the signal at the outputs of the synchronous demodulator 145 is subjected to analog-to-digital conversion at one or more times within a half-cycle and is then compared with the corresponding value for the next half-cycle. The difference is integrated and, by way of example, converted back to an analog signal and used for controlling the amplifiers 115, 120. While the synchronous demodulator 145 provides the measurement signal received from the input amplifier 140 at the lower of its outputs, the integrator 150 integrates this signal over time and provides the result at its output. While the synchronous demodulator 145 provides the measurement signal received from the input amplifier 140 at its upper output, this signal is integrated by the integrator 150 in inverted form over time and the result is provided at the output of the integrator 150. The voltage at the output of the integrator 150 is the integral of the difference between the low-pass-filtered outputs of the synchronous demodulator 145.

If the capacitance at the first transmission electrode 125 is of precisely the same magnitude as the capacitance at the second transmission electrode 130, the signals provided at the outputs of the synchronous demodulator 145 are of equal magnitude on average over time, and the output of the integrator 150 provides a signal which is virtually zero (ground). If the capacitances are of unequal magnitude, however, for example because a dielectric article is arranged in the region of only one of the transmission electrodes 125, 130, then the signals provided at the outputs of the synchronous demodulator 145 are no longer equal on average, and the output of the integrator 150 provides a positive or a negative signal. The arithmetic sign and the absolute value of the signal indicate the ratio of the capacitances, with a signal of zero corresponding to a ratio of one.

The signal provided by the integrator 150 is provided for an evaluation and output device—not shown—in the beam finder 105 via a connection 155. By way of example, the evaluation device can perform a comparison with a threshold value, as a result of which a user of the locator 105 is provided with a visual and/or audible output when the signal provided by the integrator 150 exceeds a predetermined threshold. In this case, the entire signal or an absolute value of the signal can be compared with the threshold value.

The signal provided by the integrator 150 is also used for controlling the gain factors of the controllable amplifiers 115 and 120, the second controllable amplifier 120 being connected directly to the output of the integrator 150, and the first controllable amplifier 115 being connected to the output of the integrator 150 by means of an inverter 160. The inverter 160 prompts inversion of the signal with which it is provided such that the gain factor of the first controllable amplifier 115 increases on the basis of the output signal from the integrator 150 by the amount by which the gain factor of the second controllable amplifier 120 decreases, or vice versa. It is also conceivable for only the gain factor of one of the controllable amplifiers 115, 120 to be controlled, while the gain factor of the second controllable amplifier 120, 115 is kept at a fixed value.

The gain factors of the controllable amplifiers 115 and 120 increase or decrease until an AC voltage component which is in sync with the alternating voltage applied to the transmission electrodes 125 and 130 and which is applied to the reception electrode is minimized in terms of absolute value.

The push-pull measurement bridge 100 is a control loop which is set up to maintain a predetermined ratio at the transmission electrodes 125 and 130. The predetermined ratio is prescribed by the setup and arrangement of the transmission electrodes 125 and 130 relative to one another and relative to the reception electrode 135. A variable ratio is obtained from the capacitances formed on the transmission electrodes 125 and 130 relative to the reception electrode 135. The signal provided by the integrator 150 is a control signal for compensating for an asymmetrical influence on the capacitances, for example by the dielectric article. In other embodiments, the variable ratio at the electrodes is determined on the basis of currents or voltages at the electrodes.

At each of the transmission electrodes 125, 130, the compensating network 165 comprises a voltage divider consisting of two impedances. The divided voltages are routed to the input amplifier 140 by means of a respective further impedance. The reception electrode 135 is routed to the input amplifier 140 not directly but rather by means of the impedance 170. Through an appropriate choice of the individual cited impedances, it is possible to alter the impedances that are effective at the outputs of the controllable amplifiers 115, 120. This makes it possible to compensate for an asymmetrical arrangement of the electrodes 125-135, for example.

In a further embodiment, in comparison with the illustration in FIG. 1, the compensating network 165 dispenses with the impedances in the region of the first transmission electrode 125 and also with the second transmission electrode 130. Hence, the alternating voltages from the controllable amplifiers 115, 120 are balanced out between a capacitance that is present at the first (single) transmission electrode 125 and a reference capacitance that is formed by the compensating network 165. The reference capacitance is invariant toward a dielectric article. Measurements now require only the first transmission electrode 125 and the reception electrode 135.

A converse embodiment, in which, in comparison with the illustration in FIG. 1, the compensating network 165 dispenses with the impedances in the region of the second transmission electrode 130 and also with the first transmission electrode 125, is likewise possible.

The provision of switches allows the push-pull measurement bridge 100 according to the described embodiments to be operated in a three-electrode measurement mode by using two transmission electrodes 125 and 130, a first two-electrode measurement mode by using the first transmission electrode 125 and the reception electrode 135, and also a second two-electrode measurement mode by using the second transmission electrode 130 and the reception electrode 135. Changeover between the various measurement modes can be effected cyclically or may be controlled by a user.

Whereas, in the two-electrode measurement mode, a voltage applied to the connection 155 of the push-pull measurement bridge 100 in FIG. 1 is highest when the dielectric article is closest to the reception electrode 135, the absolute value of this voltage in the three-electrode measurement mode is at a maximum when the dielectric article is closest to one of the transmission electrodes 125 and 130, with the arithmetic sign of the voltage indicating the respectively closest transmission electrode. When the article is moved past the electrodes, the three-electrode measurement mode thus provides a signal having a change of arithmetic sign and the two-electrode measurement mode provides a signal having a local maximum at the moment of passage.

In a related embodiment, the push-pull measurement bridge 100 can be used to sense a metallic article. To this end, the first transmission electrode 125 is replaced by a first transmission coil 175, and the second transmission electrode 130 is replaced by a second transmission coil 180. The reception electrode 135 is replaced by a single reception coil 185 or by a system of reception coils, preferably two reception coils that are connected in series with one another.

Preferably, at least one of the coils is in the form of a conductor structure on a circuit board (“printed coil”). In a further embodiment, the reception electrode 135 is replaced by a single magnetoresistive magnetic field sensor, preferably a Hall sensor, or by a system of magnetoresistive sensors, preferably two magnetoresistive sensors that are connected in series with one another. In a further embodiment, instead of the reception electrode 135, magnetoresistive magnetic field gradient sensors are used.

The text below explains the push-pull measurement bridge 100 by using the reception coil 185. The use of a system of reception coils 185 or of magnetoresistive magnetic field sensors or magnetic field gradient sensors is effected in a similar manner.

The transmission coils 175, 180 produce superimposed magnetic fields having periodically changing amplitudes and phases. Preferably, both transmission coils 175, 180 use each half-cycle of their supply voltage to produce magnetic fields having the same amplitude and parallel orientation of the main field directions. The arithmetic sign of the magnetic fields alternates from half-cycle to half-cycle. To this end, the transmission coils 175 and 180 are wound in opposite senses and the free ends of said coils are each connected to ground.

The supply of voltage by the controllable amplifiers 115, 120 is effected with voltages that are opposed in respect of ground. Alternatively, the transmission coils 175 and 180 use a half-cycle to produce magnetic fields having a different amplitude and parallel or antiparallel orientation of the main field direction. The amplitude and the arithmetic sign of the magnetic field produced by the transmission coil 175 in a half-cycle correspond to the amplitude and arithmetic sign respectively of the magnetic field produced by the transmission coil 180 in the preceding or subsequent half-cycle. To this end, the winding senses of the transmission coils 175, 180 and also the supply voltages for the transmission coils 175, 180 with reference to ground need to be adapted accordingly.

The reception coil 185 is arranged in the region of the transmission coils 175 and 180 such that it is exposed to the superimposed magnetic field from both transmission coils 175 and 180. Preferably, the arrangement of the coils 175 to 185 is chosen such that the voltage induced in the reception coil 185 by the magnetic fields from the transmission coils 175 and 180 is zero, but at least constant, when the two controllable amplifiers 115 and 120 have the same gain factors.

When only one reception coil 185 is used, the transmission coils 175 and 180 may be arranged coaxially in two parallel planes, for example, and the reception coil 185 is arranged in a third parallel plane which is at the same distance from each of the first two planes. When a system comprising two interconnected reception coils 185 is used, the transmission coils 175 and 180 may be arranged in two parallel planes. The two interconnected reception coils 185 may each be arranged in one of the two parallel planes, preferably such that the orientation and position of each of the transmission coils 175, 180 corresponds to the orientation and position of each of the reception coils 185. The winding sense and interconnections of the reception coils 185 are determined from the condition that the voltage induced across the system of reception coils 185 is zero when the two controllable amplifiers 115 and 120 have the same gain factors. If the two transmission coils 175, 180 use each half-cycle to produce magnetic fields having the same amplitude and parallel orientation of the main field direction, and the arithmetic sign of the magnetic fields alternates from half-cycle to half-cycle, this condition is met, for example, when the two reception coils 185 are connected in series and are wound in opposite senses. If the two reception coils 185 are operated in an antiserial series circuit, the reception coils 185 must be wound in the same sense. For the further cases—described above—of alternative magnetic fields produced by the transmission coils and superimposed, the result is analogous combinations of the interconnection of the reception coils 185 and the relative orientation of the winding sense of the reception coils 185. The predetermined ratio for the transmission coils 175 and 180 is 1 in this case.

In respect of the omission of coils 180, 185 and the use of the compensating network 165 and the impedance 170, the above explanations regarding the embodiment for determining a dielectric article apply in corresponding fashion.

The transmission coils 175 and 180 are at positions which are at least slightly axially or laterally offset from one another, which means that a metallic article generally adopts different distances from the transmission coils 175 and 180. It is possible to prevent the article from being located in a plane between the transmission coils 175 and 180, in which plane the article is at the same distance from the transmission coils 175 and 180 in the case of axially offset transmission coils 175, 180, by virtue of the arrangement of the transmission coils 175 and 180 in the locator 105. The asymmetrical position of the article relative to the transmission coils 175 and 180 means that the article is influenced by the magnetic fields from the transmission coils 175 and 180 in different ways. Accordingly, the magnetic fields are also influenced by the metallic article in different ways, as a result of which the voltage induced by the superimposed magnetic fields in the reception coil 185 is no longer zero. The push-pull measurement bridge 100 compensates for this asymmetry by virtue—as explained above—of one of the amplifiers 115 and 120 being actuated to produce a higher gain factor than the other of the amplifiers 115, 120 until the voltage induced by the superimposed magnetic fields in the reception coil 185 has reached the value zero again. The variable ratio between the transmission coils 175 and 180 then no longer corresponds to 1 and the connection 155 has a voltage applied to it which is not equal to zero. Comparison of the voltage applied to the connection 155 with the predetermined value zero (corresponding to the predetermined ratio one) allows the metallic article to be sensed.

FIG. 2 shows a schematic illustration of the locator 105 with the push-pull measurement bridge 100 from FIG. 1. The locator 105 comprises a processing device 205 which is connected to the push-pull measurement bridge 105. In addition, the processing device 205 is connected to a voltage sensor 210 and a power controller 215, which for its part is connected to a battery 220 and a charging socket 225. Furthermore, the processing device 205 is connected to a data interface 230, a visual output device 235, an audible output device 240, an input device 245 and a position sensor 250.

To allow simpler referencing, the first transmission electrode 125 and the first transmission coil 175 are referred to here as the first electromagnetic device 190. Correspondingly, the second transmission electrode 130 and the second transmission coil 180 are referred to as the second electromagnetic device 195, and the reception electrode 135 and the reception coil 185 are referred to as the third electromagnetic device 198.

In the embodiment shown, the push-pull measurement bridge 100 is of separate design from the processing device 205. In another embodiment, elements of the push-pull measurement bridge 100 may also be formed by the processing device 205. The processing device 205 is preferably an ordinary digital microcomputer having an operating clock generator and program and data memories. For the conversion between digital signals of the processing device 205 and analog signals within the push-pull measurement bridge 100, one or more digital-analog converters (DAC) and at least one analog-digital converter (ADC) may be provided. In particular, the processing device 205 may implement the clock generator 110, the controllable amplifiers 115 and 120, the synchronous demodulator 145, the integrator 150 and/or the inverter 160. The signal from the push-pull measurement bridge 105, which signal is provided at the connection 155 and indicates the variable ratio for the first and second electromagnetic devices 190 and 195, can also be evaluated by means of the processing device 205. This includes the comparison of the signal with a predetermined value and the determination of whether the difference between the signal and the predetermined value exceeds a predetermined amount. In another embodiment, the functionalities described may also be implemented by discrete components, for example by analog electronic circuits or in the form of a user-specific IC (ASIC).

The voltage sensor 210 is a known sensor which senses an electromagnetic field which is generated by a current-carrying or voltage-carrying conductor. In one embodiment, exclusively electromagnetic alternating fields in a predetermined frequency range are detected by the voltage sensor 210, for example in the frequency range above 20 Hz, preferably in a range from approximately 45 to 65 Hz. With further preference, the voltage sensor 210 determines the electromagnetic field by means of the electrical voltage that is applied to a measurement electrode of the voltage sensor 210 on the basis of the electrical field.

In addition to the voltage sensor 210, further auxiliary sensors—not shown—for improving a measurement result from the push-pull measurement bridge 100 may be connected to the processing device 210. By way of example, these include a sensor which determines whether the electromagnetic devices 190 to 198 are oriented relative to a measurement area as required, particularly whether distances between the measurement area and the electromagnetic devices 190 to 198 are of equal magnitude. This makes it possible to prevent the locator 105 from being tilted relative to the measurement area. The measurement area is usually the surface of a body which holds the article to be sensed. The body may be a wall and the article may be concealed therein.

The power controller 215 supplies the locator 105 with voltages which are required for operation. Usually, the electrical power required for this purpose is taken from the battery 220. To charge the battery 220, the power controller 215 can be supplied with electrical power via the charging socket 225, with the power controller 215 controlling and monitoring the charging of the battery 220. It is likewise possible for the locator 105 to be operated on the basis of electrical power which is supplied exclusively via the charging socket 225. The charging socket 225 is usually a low-voltage connector, the counterpart of which is connected to a power supply unit. In one embodiment, a charging station may be provided, into which the locator 105 is placed, with the charging socket 225 being electrically connected to the power supply unit, so that the battery 220 can be charged. In a further embodiment, the power supply unit may also be held in the locator 105 and the charging socket 225 can be connected to the usual power supply system.

Parts of the logic for supplying the locator 105 with electrical power and for controlling the charging process of the battery 220 may be implemented by the processing device 205. In addition, the processing device 205 can influence the power controller 215, for example in the form of automatic switch-off of the locator 105 after a predetermined time in which the locator 105 has not been used, or in the form of a check on a present charge state of the battery 220.

The data interface 230 can be used by the processing device 205 to interchange information with an external appliance. Such information may relate to measurement results which have been collected or are held in a memory in the processing device 205. The data interface 230 and the charging socket 225 may be in a form in which they are integrated with one another. Preferably, the data interface 230 is a digital serial data interface, particularly a USB interface.

In a first embodiment, the visual output device 235 comprises a number of light-emitting diodes for visually displaying a measurement result from the push-pull measurement bridge 100. Further light-emitting diodes for presenting internal states of the locator 105 may likewise be included, for example for indicating a charge state of the battery.

In a second embodiment, which can be combined with the first embodiment, the visual display device 235 comprises a graphical display, for example a liquid-crystal display (LCD). The LCD may comprise a backlight, for example using LEDs or OLEDs, and may comprise a region with a dot matrix which can be used to selectively display individual points. Both the LCD and the backlight or the light-emitting diodes in the first exemplary embodiment are able to support a plurality of output colors. In one preferred embodiment, the visual output device is designed such that it is possible for the locator 105 to be operated either in a bright environment or in a dark environment. To this end, a luminous brightness of the LEDs or of the backlight in the LCD can be adapted to the light conditions in the environment.

The audible output device 240 may comprise a loudspeaker or a piezo transducer. The presentation of a measurement result from the push-pull measurement bridge 100 can be output visually, audibly or in a combination of visually and audibly by means of the visual output device 235 and the audible output device 240. By way of example, a position of a sensed article can be displayed on the visual output device 235 while a characteristic sound from the audible output device 240 indicates a metallic property of the article. A color of the visually presented article can symbolize a distance, particularly a depth of the article. Associations between the color and sound and properties of the article (metallic, dielectric, voltage-carrying) may be alterable, in one embodiment also by a user of the locator 105.

The input device 245 can be used by the user to operate the locator 105. The input device 245 may comprise a number of keys which may be combined in a keypad. In one embodiment, the input device 245 merely comprises a single key, with complete ease of use of the locator 105 being ensured by means of this one key. The input device 245 may be partially or completely backlit. The backlight may be coupled to a backlight of the visual output device 235. Alternatively or in addition, the backlight may be user-controlled. In addition, the input device 245 may comprise further input means, particularly a rotary or slide control. Such a control may be sampled in analog or digital fashion and, in particular, used for changing a parameter of the locator 105 smoothly or in fine steps. Such a control can be used to set a sensitivity for the push-pull measurement bridge 100. Furthermore, the input device 245 may be designed to be wholly or partially integrated with the visual output device 235 in the form of a touch-sensitive screen “touch screen”.

The position sensor 250 is used to determine a position for the locator 105 relative to the measurement area by sensing a displacement of the locator 105 relative to the measurement area. The sensing can take place in one dimension or in two dimensions. To this end, it is possible to use an acceleration sensor, for example, preferably a micromechanical acceleration sensor. Alternatively, a wheel may be arranged in the region between the locator 105 and the measurement area, with a rotation of the wheel being converted into a displacement by the processing device 205. In the two-dimensional case, a mechanism similar to that in a computer mouse can be used by virtue of a trackball being held between the locator 105 and the measurement area, and a displacement of the locator 105 being sampled in two dimensions on the basis of a movement of the trackball. In yet a further embodiment, optical sampling in a similar manner to in an optical computer mouse can be performed, with the position sensor 250 comprising a camera which is directed onto the measurement area, and the position sensor 250 converting a displacement of the image taken by the camera into a displacement of the locator 105 relative to the measurement area. The conversion can also be performed by the processing device 205. A light source, for example in the form of one or more light-emitting diodes, may be arranged in the region of the camera.

Instead of the one push-pull measurement bridge 100 shown, a plurality of push-pull measurement bridges 100 may also be included by the locator 105 and connected to the processing device 205. In addition, various electromagnetic devices 190 to 198 may, under the control of the processing device 205, be able to be connected to the one or more push-pull measurement bridges 100, with the result that electromagnetic devices 190 to 198 of different design or situated at different positions can be used to perform measurements.

FIG. 3 shows various arrangements of the electromagnetic devices 190 to 198 for the push-pull measurement bridge 100 from FIG. 1. FIG. 3A shows a matrix-like arrangement. The third electromagnetic element 198 forms the central element of a 3×3 matrix, the remaining elements of which are formed by first and second electromagnetic devices 190, 195. In respect of the third electromagnetic element 198, a first electromagnetic element 190 and a second electromagnetic element 195 are respectively located opposite one another.

In chronological order, various pairs of first and second electromagnetic devices 190, 195 which are opposite one another are connected to the push-pull measurement bridge 100, so that it is possible to determine, along a line connecting the opposite devices 190, 195, on which side of the third electromagnetic device 198 the article is arranged. This allows determination of the position of the article relative to the third electromagnetic device in a plurality of directions for the plane of the electromagnetic devices 190 to 198.

FIG. 3B shows a honeycomb-like arrangement of electromagnetic devices 190 to 198. In this case, the third electromagnetic device 198 has six instead of eight adjacent electromagnetic devices 190, 195. Particularly when the electromagnetic devices 190, 195 comprise coils, the embodiment shown in FIG. 3B may be advantageous, since the coils can be brought close to the honeycomb shape in a better way than they can to the rectangular shape in FIG. 3A. It is thus possible to have an increased area packing density for the electromagnetic devices 190 to 198 in a honeycomb-shaped arrangement.

The arrangements shown in FIGS. 3A and 3B may be continued in any directions in the plane of the drawing. In this case, connecting up an electromagnetic device as a first, second or third electromagnetic device 190, 195 or 198 may be dynamically controllable. This makes it possible to support any desired size of arrangement of electromagnetic devices 190 to 198 in principle. If a plurality of push-pull measurement bridges 100 are provided in the locator 105, it is also possible for a plurality of measurements to be performed simultaneously, it being necessary to ensure a sufficient distance between active electromagnetic devices 190 to 198 in order to avoid reciprocal influencing. The electromagnetic devices 190 to 198 involved in a measurement do not have to adjoin one another but rather may be separated from one another by further, preferably not interconnected electromagnetic devices 190 to 198.

In the two-electrode measurement mode (cf. above with reference to FIG. 1), the arrangements shown in FIGS. 3A and 3B can be interconnected as appropriate.

FIG. 3C shows an exemplary embodiment of a combined measuring element 310 which comprises a disk-shaped electrode 125 to 135 which is enclosed by a round coil 175 to 185. Centers of the electrode 125 to 135 and of the coil 175 to 185 coincide in order to be able to sense articles having different properties (metallic, dielectric) relative to the same position.

The measuring element 310 can be used in the arrangements shown in FIGS. 3A and 3B. The voltage sensor 210 may be in a form integrated with one of the electromagnetic devices 190 to 198. The voltage sensor may also be arranged on a side of the electromagnetic devices 190 to 198 which is remote from the measurement area.

FIG. 4 shows a visual display of a graphical display on the locator 105 from FIG. 2. A graphical output 410 is divided into a number of display regions 420, 430 in matrix fashion. The display regions 420 are of light color and the display regions 430 are of dark color. The dark-colored display regions 430 represent positions at which the article has been sensed. Instead of a division into dark and light, it is also possible to use a grayscale or false-color presentation, with the presented grayscale or color signaling a distance of the article or a property of the article (metallic, dielectric, voltage-carrying). Each of the display regions 420, 430 corresponds to a third electromagnetic device 198 in a matrix-like arrangement as in FIG. 3A.

The output 410 provides a visual impression of a magnitude and position of the article to be sensed. FIG. 4 contains further display regions 420, 430 outside the output 410 in symbol form. These represent measurement results which have been provided and stored by means of the locator 105 from other positions. By displacing the measuring appliance 105 on the measurement area, it is possible to displace the detail about these stored measured values which is shown on the output 410. This can involve the performance of various graphical processing operations on the stored measured values. By way of example, the measured values can each represent the variable ratio, and it is possible for a comparison with the predetermined ratio and a corresponding presentation on the output 410 in light or dark each to be implemented “freshly” for the display regions 420, 430 in the region of the output 410. In this case, the predetermined ratio may have been adapted in line with input by a user. This makes it a simple matter for a user to display a contour of the article on the output 410 by displacing the locator 105 relative to the measurement area and adjusting the relevant presentation parameters for the output 410. The parameter can be adapted particularly by means of a slide or rotary control.

In a further embodiment, the grayscales and colors of the display regions 420, 430 can be replaced by a bar presentation, with the length of a bar being able to correspond to a value of the variable ratio or the deviation thereof from the predetermined ratio. This type of presentation is particularly suitable for when the locator 105 can be displaced in only one dimension relative to the measurement area. Stored display regions 420, 430 which go beyond the output 410 then consist only in an areal direction, that is to say either horizontally or vertically. If the locator 105 can be displaced vertically, the bars are preferably shown horizontally, and vice versa.

In further embodiments, stored display regions within the display can be enlarged in the manner of a magnifying glass, for example, so that a group of adjoining display regions 420, 430 visually display only one measured value.

FIG. 5 shows a view of an exemplary locator 105 as shown in FIG. 2. The locator 105 comprises just one key 245 as an input device and three light-emitting diodes 235 as a visual output device. The locator 105 is held in an approximately parallelepipedal housing 510. A lower region of the housing contains a USB socket as a combined data interface 230 and charging socket 225.

The light-emitting diodes 235 indicate a position of the article to the left or right of a center marker 520 on the housing 510. Electromagnetic devices 190 to 198—which cannot be seen—are arranged centrally relative to the center marker 520. If both light-emitting diodes 235 light with the same brightness, the article is located evenly beneath the center marker 520. In order to find an edge of the article, the locator 105 needs to be displaced until the light-emitting diodes 235 light with different brightnesses. Ideally, the edge of the article is directly beneath the center marker 520 when one light-emitting diode 235 is off and the other light-emitting diode 235 has reached maximum brightness.

The momentary-contact switch 245 controls all the functions of the locator 105. In the simplest case, the momentary-contact switch 245 is used merely to control switching-on and switching-off of the locator 105. Longer or shorter, single and multiple keystrokes on the momentary-contact switch 245 also allow the control of further functions of the locator 105, for example changeover of a sensitivity, calibration or output of the charge state of the battery 220.

1. A locator for sensing an article, comprising:
a push-pull measurement bridge configured to actuate a first electromagnetic device and a second electromagnetic device in a variable ratio, wherein the first electromagnetic device takes the actuation as a basis for producing an electromagnetic alternating field in the region of the article; and
a comparator configured to sense the article if the variable ratio differs from a predetermined ratio by more than a predetermined amount.

2. The locator as claimed in claim 1, wherein the first electromagnetic device successively produces a magnetic field and an electrical field in the region of the article.

3. The locator as claimed in claim 1, further comprising:
an apparatus for determining an electrical field from the article.

4. The locator as claimed in claim 2, further comprising:
an output device configured to output a signal when the article is sensed,
wherein the signal indicates on the basis of what type of field the article has been sensed.

5. The locator as claimed in claim 1, further comprising:
a multiplicity of first electromagnetic devices which are arranged next to one another and which are successively operated on the push-pull measurement bridge.

6. The locator as claimed in claim 5, further comprising:
a visual output device,
wherein each first electromagnetic device has an associated display region on a visual output device and an arrangement of the display regions corresponds to an arrangement of the first electromagnetic devices.

7. The locator as claimed in claim 1, further comprising:
a visual output device,
wherein a distance of the article from the locator corresponds to a change of color in the output device.

8. The locator as claimed in claim 1, further comprising:
a device configured to alter the predetermined amount.

9. The locator as claimed in claim 1, further comprising:
a distance sensor configured to ensure that the locator is lying flat on a measurement area.

10. The locator as claimed in claim 1, further comprising:
a displacement sensor configured to sense a displacement of the locator relative to the article,
wherein the locator is configured to associate a measurement result from the push-pull measurement bridge with a displacement position.

11. The locator as claimed in claim 1, further comprising:
a further push-pull measurement bridge having a third electromagnetic device and a fourth electromagnetic device;
wherein the first electromagnetic device of the push-pull measurement bridge produces an electromagnetic field with a negligibly small magnetic component, while the electromagnetic device of the other push-pull measurement bridge produces an electromagnetic field with a negligibly small electrical component, in order to sense the article on the basis of an electrical field and a magnetic field simultaneously.

12. The locator as claimed in claim 1, wherein:
the locator is held in a housing, and
the electromagnetic devices are arranged on one side of the housing.

13. The locator as claimed in claim 1, further comprising:
a visual output for outputting a visual signal that indicates the article.

14. The locator as claimed in claim 1, further comprising:
a battery for supplying power.
